(19) United States
(12) Patent Application Publication
(10) Pub. No.: US 2012/0187485 A1
(43) Pub. Date: Jul. 26, 2012

(54) SEMICONDUCTOR DEVICE AND METHOD FOR PRODUCING THE SAME

(75) Inventor: Jun MORIOKA, Yokohama-shi (JP)

(73) Assignee: Kabushiki Kaisha Toshiba, Tokyo (JP)

(21) Appl. No.: 13/204,554

(22) Filed: Aug. 5, 2011

(30) Foreign Application Priority Data
Jan. 26, 2011 (JP) 2011-014270

(51) Int. Cl. H01L 29/78

(52) U.S. Cl. 257/343; 257/E29.256

(57) ABSTRACT

According to an embodiment of the invention, a semiconductor device includes a substrate, a second conductive type source region formed in the substrate, a second conductive type drain region formed in the substrate, a first conductive type channel region formed in the substrate, a second conductive type drift region formed between the first conductive type channel region and the second conductive type drain region, an insulator film buried on a surface of the second conductive type drift region, and a gate electrode including an opening between the first conductive type channel region and the insulator film and covering a surface of the substrate from the first conductive type channel region to part of the insulator film via a gate insulator. The second conductive type drift region includes a second portion of the second conductive type drift region formed in the substrate below the opening.

### CROSS-REFERENCE TO RELATED APPLICATION

This application is based upon and claims the benefit of priority from prior Japanese Patent Application No. 2011-14270, filed on Jan. 26, 2011, the entire contents of which are incorporated herein by reference.

### FIELD

Embodiments of the present invention relate to a semiconductor device and a method for producing the semiconductor device.

### BACKGROUND

Currently there are many power devices. Among others, a DMOS (Double-diffused Metal Oxide Semiconductor) has features such as a high switching speed, high conversion efficiency in a low voltage, a high-voltage operation, and a low on-resistance. The DMOS is used as a switching element in the fields of a motor driver, a power supply, and the like, and the DMOS is used as an analog output element in the field of an audio amplifier.

Even now a semiconductor technology progresses day by day, an area of the DMOS that is an output element occupies a large proportion of a whole chip, and therefore the area of the DMOS has a large influence on chip cost. In order to reduce the area of the DMOS, it is necessary to further decrease variations of characteristics such as an on-resistance (Ron) of the DMOS. The main characteristics such as the on-resistance and a drain-to-source Breakdown Voltage (BVdss) of the DMOS are easily influenced by a spacing between a source region and a drift region that is part of a drain region, and the spacing between the source region and the drift region is easily influenced by dimensional accuracy of implantation in forming the drift region.

### BRIEF DESCRIPTION OF THE DRAWINGS

FIG. 1(a) is a plan view of a semiconductor device according to a first embodiment of the invention, and FIG. 1(b) is a sectional view of the semiconductor device of the first embodiment;

FIGS. 2A and 2B are sectional views illustrating a process of producing the semiconductor device of the first embodiment (part 1);

FIGS. 3A and 3B are sectional views illustrating a process of producing the semiconductor device of the first embodiment (part 2);

FIG. 4 is a sectional view illustrating a process of producing the semiconductor device of the first embodiment (part 3);

FIG. 5 (a) is a plan view of a semiconductor device according to a first modification of the first embodiment, and

FIG. 5 (b) is a sectional view of the semiconductor device of the first modification;

FIG. 6 (a) is a plan view of a semiconductor device according to a second modification of the first embodiment, and

FIG. 6 (b) is a sectional view of the semiconductor device of the second modification;

FIG. 7 (a) is a plan view of a semiconductor device according to a third modification of the first embodiment, and

FIG. 7 (b) is a sectional view of the semiconductor device of the third modification;

FIG. 8 (a) is a plan view of a semiconductor device according to a second embodiment of the invention, and FIG. 8 (b) is a sectional view of the semiconductor device of the second embodiment;

FIG. 9 (a) is a plan view of a semiconductor device according to a first modification of the second embodiment, and

FIG. 9 (b) is a sectional view of the semiconductor device of the first modification;

FIG. 10 (a) is a plan view of a semiconductor device according to a second modification of the second embodiment, and FIG. 10 (b) is a sectional view of the semiconductor device of the second modification;

FIG. 11 (a) is a plan view of a semiconductor device according to a third modification of the second embodiment, and FIG. 11 (b) is a sectional view of the semiconductor device of the third modification;

FIG. 12 (a) is a plan view of a semiconductor device according to a third embodiment of the invention, and FIG. 12 (b) is a sectional view of the semiconductor device of the third embodiment;

FIG. 13 (a) is a plan view of a semiconductor device according to a first modification of the third embodiment, and

FIG. 13 (b) is a sectional view of the semiconductor device of the first modification;

FIG. 14 (a) is a plan view of a semiconductor device according to a second modification of the third embodiment, and FIG. 14 (b) is a sectional view of the semiconductor device of the second modification; and

FIG. 15 (a) is a plan view of a semiconductor device according to a third modification of the third embodiment, and

FIG. 15 (b) is a sectional view of the semiconductor device of the third modification.

### DETAILED DESCRIPTION

According to an embodiment of the invention, a semiconductor device comprises: a substrate; a second conductive type source region formed in part of the substrate; a second conductive type drain region formed in part of the substrate so as to be separated from the second conductive type source region; a first conductive type channel region formed in the substrate between the second conductive type source region and the second conductive type drain region while being adjacent to the second conductive type source region; a second conductive type drift region formed between the first conductive type channel region and the second conductive type drain region while being adjacent to the second conductive type drain region; an insulator film buried on a surface of the second conductive type drift region while separated from the first conductive type channel region; and a gate electrode including an opening between the first conductive type channel region and the insulator film, and covering a surface of the substrate from the first conductive type channel region to part of the insulator film via a gate insulator. The second conductive type drift region comprises a second portion of the second conductive type drift region formed in the substrate below the opening and a first portion of the second conductive type drift region, the first portion being a portion other than the second portion in the second conductive type drift region.

Embodiments of the present invention will be described below with reference to the drawings. However, the present invention is not limited to the embodiments. In the drawings, common component is designated by the same numeral, and the overlapping description will not be repeated. The drawings are used only by way of example in order to describe and comprehend the embodiments. Although sometimes shapes, dimensions, ratios are different from those of an actual apparatus, the design change can appropriately be performed to the shapes, dimensions, ratios by making allowance for the following description and the well-known art.

### First Embodiment

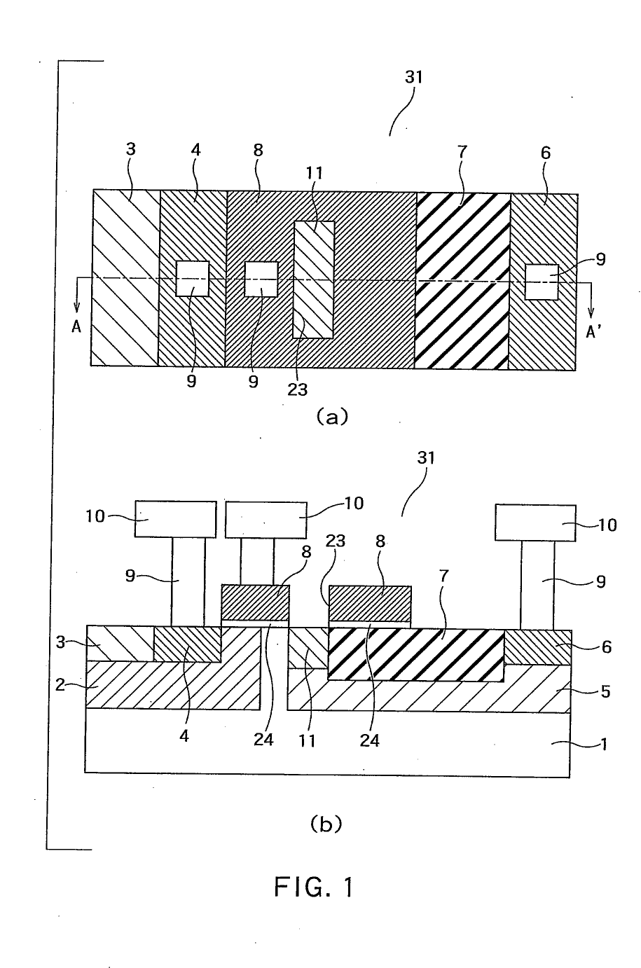

A semiconductor device 31 according to a first embodiment of the invention will be described with reference to FIG. 1. Although an N-type channel LDMOS is described below by way of example, the invention is not limited to the N-type channel LDMOS. For example, the invention can also be applied to other semiconductor devices such as a DMOS, an LDMOS (Lateral DMOS), a DEMOS (Drain Extended MOS), an EDMOS (Extended Drain MOS), and a MOSFET (MOS Field Effect Transistor).

FIG. 1 (a) is a plan view of the LDMOS (semiconductor device) 31 of the first embodiment, and FIG. 1 (b) is a sectional view of the LDMOS 31. FIG. 1 (b) is the sectional view taken on a line A-A′ of FIG. 1 (a).

As illustrated in FIG. 1 (a), in the LDMOS 31 of the first embodiment, a P-type back gate (BG) region 3, an N-type source region 4, a gate electrode 8, a field oxide film (insulator film) 7, and an N-type drain region 6 are sequentially disposed from the left on a semiconductor substrate 1. The field oxide film 7 serves as the insulator film in the LDMOS 31. For example, 0.18 μm by 0.18 μm electrode regions 9 are disposed in line on the N-type source region 4, the gate electrode 8, and the N-type drain region 6. An opening 23 is provided in a central portion of the gate electrode 8 to expose a surface of an N-type drift region 11 (a second portion in a drift region). In FIG. 1 (a), the opening 23 is formed into a rectangular shape having a length of, for example, 0.2 μm in a crosswise direction and a length of 0.6 μm in a longitudinal direction. The opening 23 is not limited to the rectangular shape having the dimensions. In FIG. 1 (a), the electrode regions 9 of the N-type source region 4, the gate electrode 8, and the N-type drain region 6 and the opening 23 of the gate electrode 8 are arrayed in line. However, there is no limitation to the disposition of FIG. 1 (a). It is only necessary to dispose the electrode region 9 of the N-type source region 4 on the N-type source region 4, it is only necessary to dispose the electrode region 9 of the gate electrode 8 on the gate electrode 8, and it is only necessary to dispose the electrode region 9 of the N-type drain region 6 on the N-type drain region 6. For the sake of easy understanding, an interconnection layer 10 disposed on the electrode region 9 is not illustrated in FIG. 1 (a).

The LDMOS 31 of the first embodiment will be described with reference to FIG. 1 (b). In FIG. 1 (b), as can be seen from FIG. 1 (a), a left edge portion is a source side and a right edge portion is a drain side. In the LDMOS 31, a P-type body region 2 is disposed in part of an upper portion on the source side in the P-type or N-type semiconductor substrate 1 made of, for example, single-crystal silicon. In the LDMOS 31, the P-type body region 2 also acts as a channel region. Alternatively, the channel region may be formed independently of the P-type body region 2.

The P-type back gate region 3 is disposed in part of an upper portion on the source side in the P-type body region 2. The N-type source region 4 is provided in part of the center of the upper portion in the P-type body region 2 so as to be in contact with a side surface on the drain side in the P-type back gate region 3.

An N-type drift region 5 (a first portion in the drift region) having a depth of, for example, 300 to 600 nm is provided in part of the upper portion on the drain side of the semiconductor substrate 1 so as to be separated from the P-type body region 2. In the upper portion of the N-type drift region 5, the N-type drain region 6 is disposed in a drain side edge portion, the field oxide film 7 having a depth of 300 nm is made of, for example, oxide silicon in the upper portion (surface) of the N-type drift region 5 between the P-type body region 2 and the N-type drain region 6, and the field oxide film 7 is buried so as to be separated from the P-type body region 2 and so as to be in contact with the side surface on a source side in the N-type drain region 6. The field oxide film 7 is not limited to the STI (Shallow Trench Isolation) structure, but the field oxide film 7 may be formed by a LOCOS (Local Oxidation of Silicon) structure. The field oxide film 7 may be eliminated in low-voltage semiconductor devices.

As described above, the LDMOS 31 of the first embodiment includes the semiconductor substrate 1, the N-type source region 4 that is formed in part of the semiconductor substrate 1, the N-type drain region 6 that is formed in part of the semiconductor substrate 1 so as to be separated from the N-type source region 4, the P-type body region 2 that is formed in the semiconductor substrate 1 between the N-type source region 4 and the N-type drain region 6 while being adjacent to the N-type source region 4, the N-type drift region 5 that is formed between the P-type body region 2 and the N-type drain region 6 while being adjacent to the N-type drain region 6, and the field oxide film 7 that is buried on the surface of the N-type drift region 5 so as to be separated from the P-type body region 2.

The N-type drift region 11 having a depth of, for example, 300 to 600 nm is disposed between the P-type body region 2 and the field oxide film 7 in the N-type drift region 5 so as to be separated from the P-type body region 2 and so as to be in contact with the side surface on the source side of the field oxide film 7. An impurity concentration of the N-type drift region 11 is higher than that of the N-type drift region 5, and a resistance value of a region that is in contact with the side surface on the source side of the field oxide film 7 can be decreased by the N-type drift region 11. Preferably the depth of the N-type drift region 11 is shallower than that of the N-type drift region 5 such that the impurity concentration is increased near the surface of the semiconductor substrate 1. In the first embodiment, the impurity concentration of the N-type drift region 11 is lower than that of the N-type drain region 6 and higher than that of the N-type drift region 5. Alternatively, the impurity concentration of the N-type drift region 11 may be equal to that of the N-type drift region 5. The position of the N-type drift region 11 is determined in consideration of the characteristics such as the drain-to-source Breakdown Voltage and the on-resistance of the LDMOS 31. When the impurity concentration of the N-type drift region 11 is equal to that of the N-type drift region 5, the position of the N-type drift region 11 is determined in consideration of the characteristics such as the drain-to-source Breakdown Voltage and the on-resistance of the LDMOS 31 and the disposition of the N-type drift region 5.

The gate electrode 8 is provided on the surface of the semiconductor substrate 1. The gate electrode 8 covers the surface of the semiconductor substrate 1 from the drain side edge portion of the P-type body region 2 located on the left of FIG. 1(b) to a half of the source side of the field oxide film 7 located on the right of FIG. 1 (b), via a gate insulator 24. In addition, the gate electrode 8 includes the opening 23 between the drain side edge portion of the P-type body region 2 and the field oxide film 7, and the gate insulator 24 has a thickness of, for example, 13 nm. The gate electrode 8 has the thickness of, for example, 200 nm. The gate insulator 24 can be made of, for example, a silicon oxide film and the gate electrode 8 can be made of, for example, a polysilicon film. The N-type drift region 11 is provided below the opening 23, in other words, the opening 23 is formed so as to expose the surface of the N-type drift region 11. The side surface on the source side of the N-type drift region 11 is formed so as to be aligned with the side surface on the source side of the opening 23. In FIG. 1(b), the side surface on the source side of the N-type drift region 5 and the side surface on the source side of the N-type drift region 11 are formed so as to be aligned with each other. Alternatively, compared with the side surface on the source side of the N-type drift region 11, the side surface on the source side of the N-type drift region 5 may be disposed on the source side or the drain side.

The electrode regions 9 are disposed on the gate electrode 8, the N-type source region 4, and the N-type drain region 6, and the interconnection layers 10 are disposed on the electrode regions 9, respectively.

The semiconductor substrate 1 has the impurity concentration of 1e14 to 1e16 cm⁻³, the P-type body region 2 has the impurity concentration of 1e15 to 5e18 cm⁻³, the P-type back gate region 3 has the impurity concentration of 5e19 to 1e21 cm⁻³, the N-type source region 4 has the impurity concentration of 5e19 to 1e21 cm⁻³, the N-type drift region 5 has the impurity concentration of 1e15 to 1e18 cm⁻³, the N-type drain region 6 has the impurity concentration of 5e19 to 1e21 cm⁻³, and the N-type drift region 11 has the impurity concentration of 5e15 to 5e18 cm⁻³.

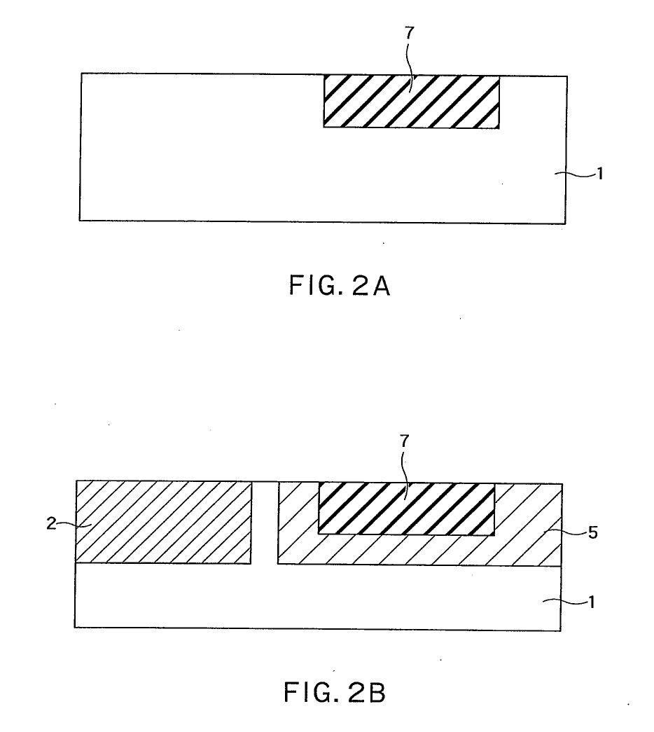

A method of producing the LDMOS 31 of the first embodiment will be described below with reference to FIGS. 2 to 4. FIGS. 2 to 4 are sectional views of processes of the method of producing the LDMOS 31 of FIG. 1.

As illustrated in FIG. 2A, the field oxide film 7 having the depth of, for example, 300 nm is formed on the P-type or N-type semiconductor substrate 1 to separate the source side located on the left of FIG. 2A and the drain side located on the right of FIG. 2A.

Then, as illustrated in FIG. 2B, the P-type body region 2 is formed in part of the upper portion of the semiconductor substrate 1 on the source side while separated from the field oxide film 7. The N-type drift region 5 (a first second-conductive-type drift region) is formed in part of the upper portion of the semiconductor substrate 1 on the drain side through the field oxide film 7. In other words, the N-type drift region 5 in which the field oxide film 7 is formed on the surface thereof is formed. The P-type body region 2 and the N-type drift region 5 may be formed in no particular order. The N-type drift region 5 may be formed before or after the field oxide film 7 is formed. In the first embodiment, the P-type body region 2 constitutes the channel region. Alternatively, the channel region may be formed independently of the P-type body region 2. For the N-type semiconductor substrate 1, the process of forming the N-type drift region 5 may be eliminated.

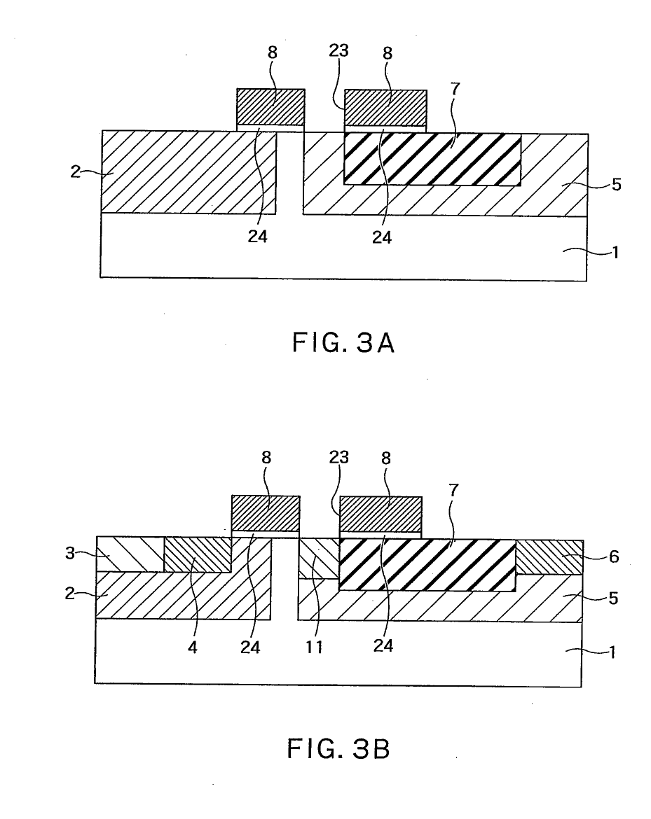

The gate insulator 24 having the thickness of, for example, about 13 nm is formed from the drain side edge portion of the P-type body region 2 to the half of the source side of the field oxide film 7, and the gate electrode 8 having the thickness of thickness of 200 nm is made of, for example, the poly-silicon film. As illustrated in FIG. 3A, the gate insulator 24 and the gate electrode 8 are patterned into a desired shape using a photolithography technique and an etching technique such as RIE (Reactive Ion Etching). Particularly, the gate insulator 24 and the gate electrode 8 are formed so as to cover the surface of the semiconductor substrate 1 from the drain side edge portion of the P-type body region 2 to the half of the source side of the field oxide film 7, in order to utilize a field plate effect to decrease a potential difference. In FIG. 3A, the opening 23 having the rectangular shape of, for example, 0.2 μm by 0.6 μm is formed so as to be located between the P-type body region 2 and the field oxide film 7 and so as to expose the surface in the region where the N-type drift region 11 (a second second-conductive-type drift region) that is in contact with the side surface on the source side of the field oxide film 7 is formed. There is no particular limitation to the dimension or shape of the opening 23.

As illustrated in FIG. 3B, by the implantation with the patterned gate electrode 8 and gate insulator 24 as a hard mask, the impurity is added through the opening 23 to form the N-type drift region 11 connected to the N-type drift region 5. Preferably the depth of the N-type drift region 11 is shallower than that of the N-type drift region 5 such that the impurity concentration is increased near the surface of the semiconductor substrate 1. Therefore, the N-type drift region 11 having the depth of, for example, 300 to 600 nm is formed at the position corresponding to the opening 23. The gate electrode 8 and the gate insulator 24 are accurately formed because the gate electrode 8 and the gate insulator 24 constitute part of the LDMOS 31. Accordingly, in the first embodiment, the N-type drift region 11 can accurately be formed at the desired position with the accurately-formed gate electrode 8 and gate insulator 24 as the mask for the implantation. The increases of the production time and the production cost can be avoided because the gate electrode 8 and the gate insulator 24 that constitute the part of the LDMOS 31 are used as the mask.

Then, as illustrated in FIG. 3B, the P-type back gate region 3 and the N-type source region 4 are formed in part of the upper portion of the P-type body region 2, and the N-type drain region 6 is formed in the drain region 21 of N-type drift region 5.

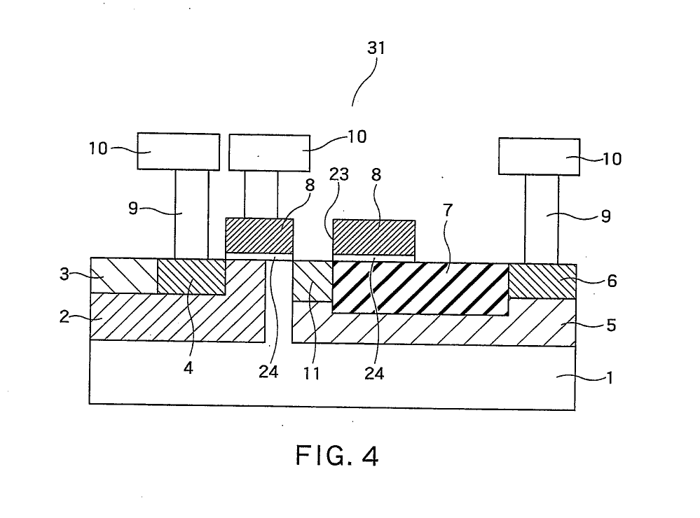

As illustrated in FIG. 4, the electrode regions 9 and the interconnection layers 10 are formed.

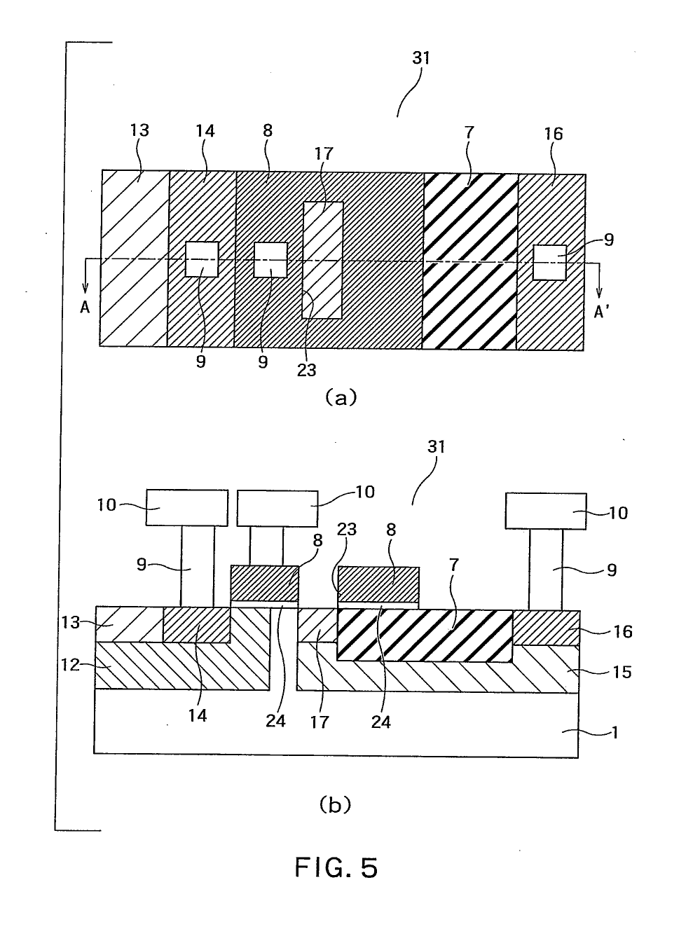

The LDMOS 31 of the first embodiment can also be applied to a P-type channel semiconductor device. FIG. 5 (a) is a plan view of a P-type channel LDMOS 31 according to a first modification of the first embodiment, and FIG. 5 (b) is a sectional view of the P-type channel LDMOS 31. FIG. 5 (b) is the sectional view taken on a line A-A′ of FIG. 5 (a).

As illustrated in FIG. 5 (a), in the first modification of the first embodiment, an N-type back gate region 13, a P-type source region 14, the gate electrode 8, the field oxide film 7, and a P-type drain region 16 are sequentially disposed from the left. For example, 0.18 μm by 0.18 μm electrode regions 9 are disposed in line on the P-type source region 14, the gate electrode 8, and the P-type drain region 16. The opening 23 is provided in the central portion of the gate electrode 8 to expose a surface of a P-type drift region 17. The opening 23 of the gate electrode 8 and the electrode regions 9 of the P-type source region 14, the gate electrode 8, and the P-type drain region 16 are disposed in line. Accordingly, because the opening 23 and the electrode regions 9 are similar to those of the first embodiment, the detailed description will not be repeated. For the sake of easy understanding, the interconnection layer 10 is not illustrated in FIG. 5 (a).

Then, as illustrated in FIG. 5 (b), the LDMOS 31 of the first modification of the first embodiment includes the P-type or N-type semiconductor substrate 1, an N-type body region 12, the P-type source region 14, the N-type back gate region 13, a P-type drift region 15, the P-type drain region 16, and the field oxide film 7. Two P-type drift regions 17 are provided between the N-type body region 12 and the field oxide film 7 in the P-type drift region 15 so as to be separated from the N-type body region 12 and so as to be in contact with the side surface on the source side of the field oxide film 7. The gate electrode 8 is provided on the surface of the semiconductor substrate 1. The gate electrode 8 covers the surface of the semiconductor substrate 1 from the drain side edge portion of the N-type body region 12 to the half of the source side of the field oxide film 7, via the gate insulator 24. In addition, the gate electrode 8 includes the opening 23 that exposes the surface of the P-type drift region 17. The electrode regions 9 are disposed on the gate electrode 8, the P-type source region 14, and the P-type drain region 16, and the interconnection layers 10 are disposed on the electrode regions 9, respectively. Accordingly, because the interconnection layers 10 are similar to those of the first embodiment, the detailed description will not be repeated.

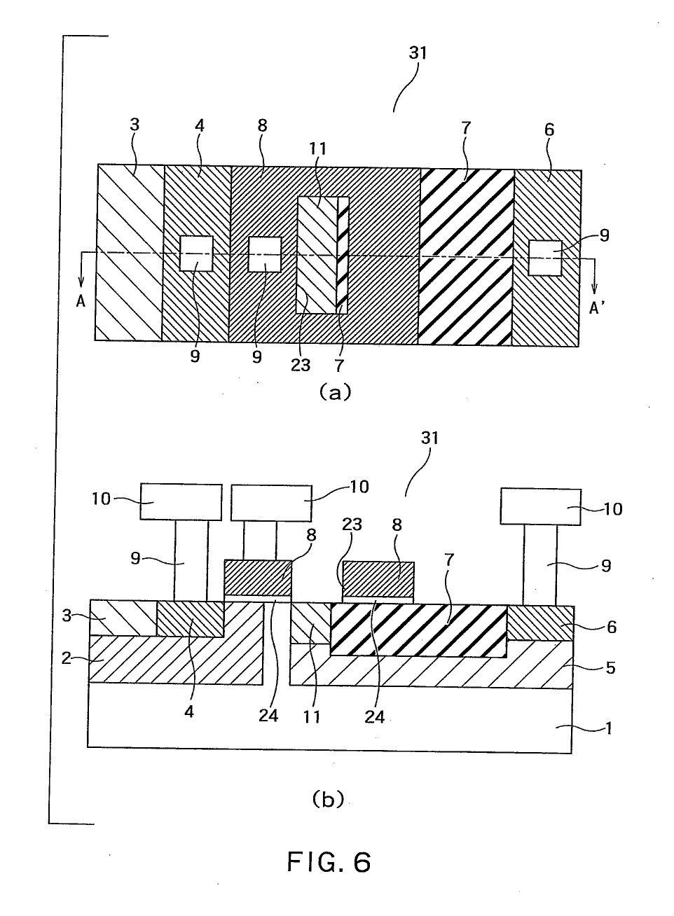

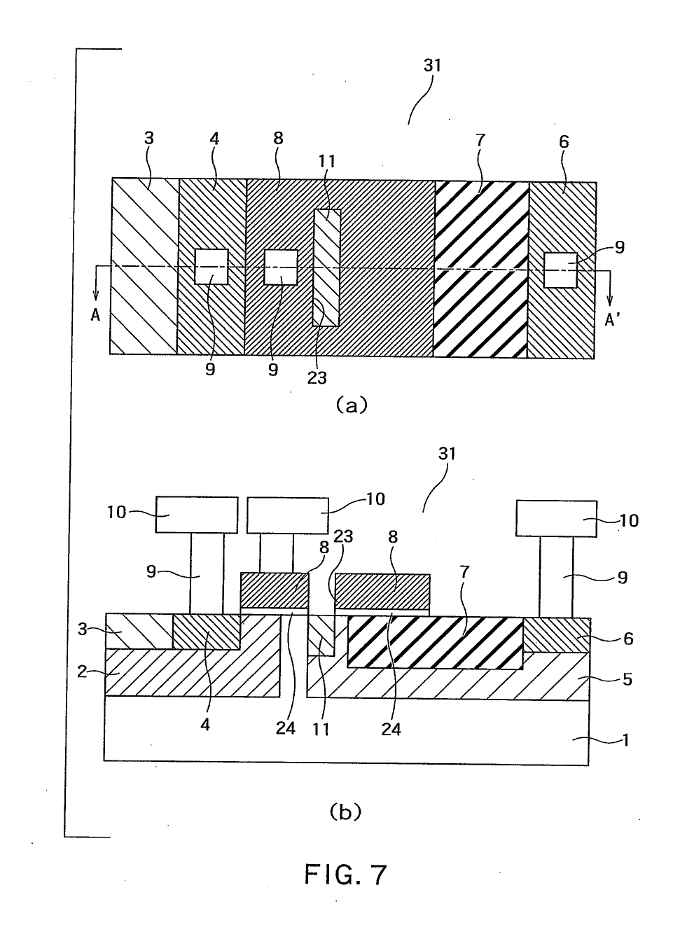

As described above, in the first embodiment, the opening 23 is formed such that the source side edge of the field oxide film 7 is aligned with the drain side edge of the opening 23 as illustrated in FIG. 1 (a). Alternatively, in a second modification of the first embodiment, as illustrated in FIG. 6, the side surface on the drain side of the opening 23 can be located on the drain side from the source side edge of the field oxide film 7. Therefore, the opening 23 is disposed with a slight margin in the region where the N-type drift region 11 should be formed, which allows the N-type drift region 11 to be securely formed at the desired position. In a third modification of the first embodiment, as illustrated in FIG. 7, the side surface on the drain side of the opening 23 can be located on the source side from the source side edge of the field oxide film 7. Therefore, the position of the N-type drift region 11 is controlled, and a passage of a carrier flowing from the source region 4 to the drain region 6 is separated from the field oxide film 7 as necessary, so that capture and emission of the carrier can be avoided in the field oxide film 7 to improve reliability of the LDMOS 31.

According to the first embodiment, the gate electrode 8 and the gate insulator 24 are used as the mask instead of the patterning performed with the resist mask in the LDMOS producing process of the related art, and the N-type drift region 11 is accurately formed at the desired position, so that the variation of the distance between the source region 4 and the drift region 11 can be reduced. Because the impurity concentration of the N-type drift region 11 is higher than the impurity concentration of the N-type drift region 5, the N-type drift region 11 has the low resistance value, and the drain-to-source Breakdown Voltage and the on-resistance, which are the main characteristics of the LDMOS 31, depend on the disposition of the N-type drift region 11. Therefore, according to the first embodiment, the variations of the characteristics can be reduced compared with the structure of the related art by reducing the variation of the distance between the source region 4 and the drift region 11. According the first embodiment, when the impurity concentration of the N-type drift region 11 is equal to that of the N-type drift region 5, even if the position of the N-type drift region 5 varies, the N-type drift region 11 can accurately be formed at the desired position on the source side of the N-type drift region 5. Therefore, the variation of the distance between the source region 4 and the drift region 11 can be reduced to reduce the variations of the characteristics such as the drain-to-source Breakdown Voltage and the on-resistance can be reduced compared with the structure of the related art.

According to the first embodiment, the increases of the production time and the production cost can be avoided with the gate electrode 8 and the gate insulator 24 as the mask.

### Second Embodiment

While the one opening 23 is provided in the first embodiment, plural openings 23 are provided in a second embodiment.

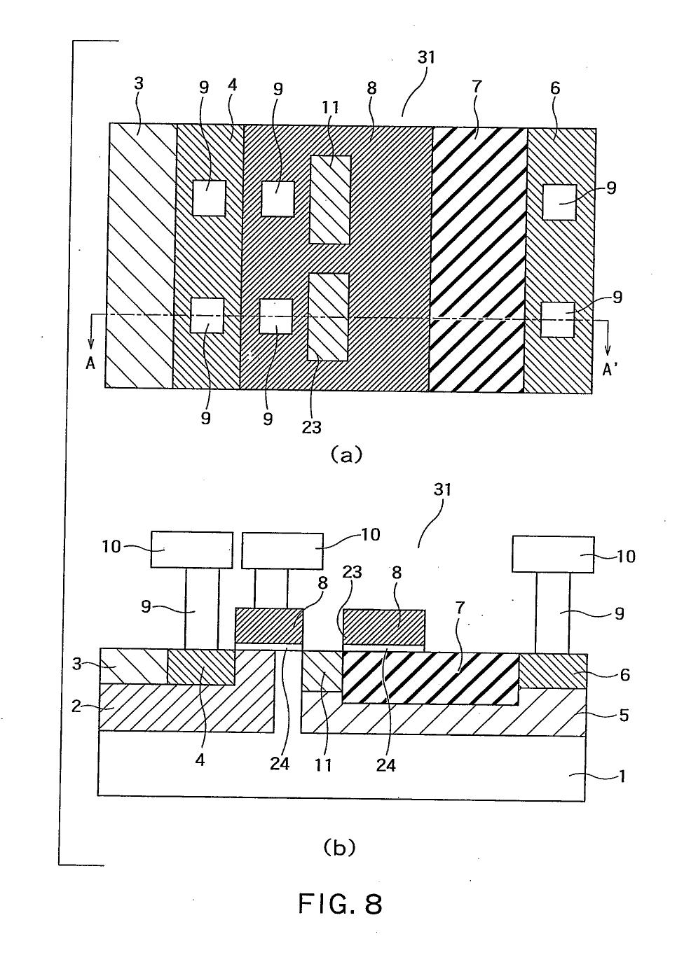

A semiconductor device 31 according to a second embodiment of the invention will be described with reference to FIG. 8. Although the N-type channel LDMOS is described by way of example in the second embodiment, the invention can be applied to other kinds of semiconductor devices.

FIG. 8 (a) is a plan view of the LDMOS (semiconductor device) 31 of the second embodiment, and FIG. 8 (b) is a sectional view of the LDMOS 31. FIG. 8 (b) is the sectional view taken on a line A-A′ of FIG. 8 (a). The LDMOS 31 of the second embodiment differs from that of the first embodiment in that the LDMOS 31 of the second embodiment includes plural openings 23 provided in the gate electrode 8 and plural N-type drift regions 11 whose surfaces are exposed by the plural openings 23. Accordingly, different points will be described below.

As illustrated in FIG. 8 (a), the two openings 23 are provided in the central portion of the gate electrode 8 to expose the surface of the N-type drift region 11. Each of the openings 23 is formed into the rectangular shape of the length of 0.2 μm in the crosswise direction of FIG. 8 (a) and the length of 0.6 μm in the longitudinal direction. The opening 23 is not limited to the shape, the number of pieces, the dimension, and the position of FIG. 8 (a), but the openings 23 may be changed according to the desired characteristics of the LDMOS 31. The two 0.18 μm by 0.18 μm electrode regions 9 are disposed on each of the N-type source region 4, the gate electrode 8, and the N-type drain region 6. In FIG. 8 (a), the electrode region 9 on the N-type source region 4, the electrode region 9 on the gate electrode 8, the opening 23 of the gate electrode 8, and the electrode region 9 on the N-type drain region 6 are arranged in line. However, the invention is not limited to the arrangement of FIG. 8 (a). It is only necessary to dispose the electrode region 9 of the N-type source region 4 on the N-type source region 4, it is only necessary to dispose the electrode region 9 of the gate electrode 8 on the gate electrode 8, and it is only necessary to dispose the electrode region 9 of the N-type drain region 6 on the N-type drain region 6. For the sake of easy understanding, the interconnection layer 10 is not illustrated in FIG. 8 (a).

Then, as illustrated in FIG. 8 (b), the two N-type drift regions 11 are formed between the P-type body region 2 and the field oxide film 7 in the upper portion of the N-type drift region 5 so as to be separated from the P-type body region 2 and so as to be in contact with the side surface on the source side of the field oxide film 7. The gate electrode 8 is formed on the surface of the semiconductor substrate 1 so as to cover the surface of the semiconductor substrate 1 from the drain side edge portion of the P-type body region 2 to the source side edge portion of the field oxide film 7 via the gate insulator 24. In addition, the gate electrode 8 includes the two openings 23 that expose the surfaces of the two N-type drift regions 11.

In the first embodiment, the P-type body region 2 that also acts as the channel region is disposed so as to be adjacent to the side surface on the source side of the N-type drift region 11, but the P-type body region 2 is not adjacent to the side surface on the source side of the N-type drift region 5 where the N-type drift region 11 is not formed (in FIG. 1 (a), the side surface on the source side in the portion of the N-type drift region 5, which is covered with the portion of the gate electrodes 8 vertically disposed in the opening 23). On the other hand, in the second embodiment, the P-type body region 2 that also acts as the channel region can be disposed so as to be adjacent to the side surface on the source side of the N-type drift region 11 and the side surface on the source side in the portion of the N-type drift region 5, which is sandwiched between the N-type drift regions 11 (in FIG. 8 (a), the side surface on the source side in the portion of the N-type drift region 5, which is covered with the portion of the gate electrodes 8 disposed between the openings 23).

Because a method of producing the N-type channel LDMOS 31 of the second embodiment is similar to that of the first embodiment, the description will not be repeated.

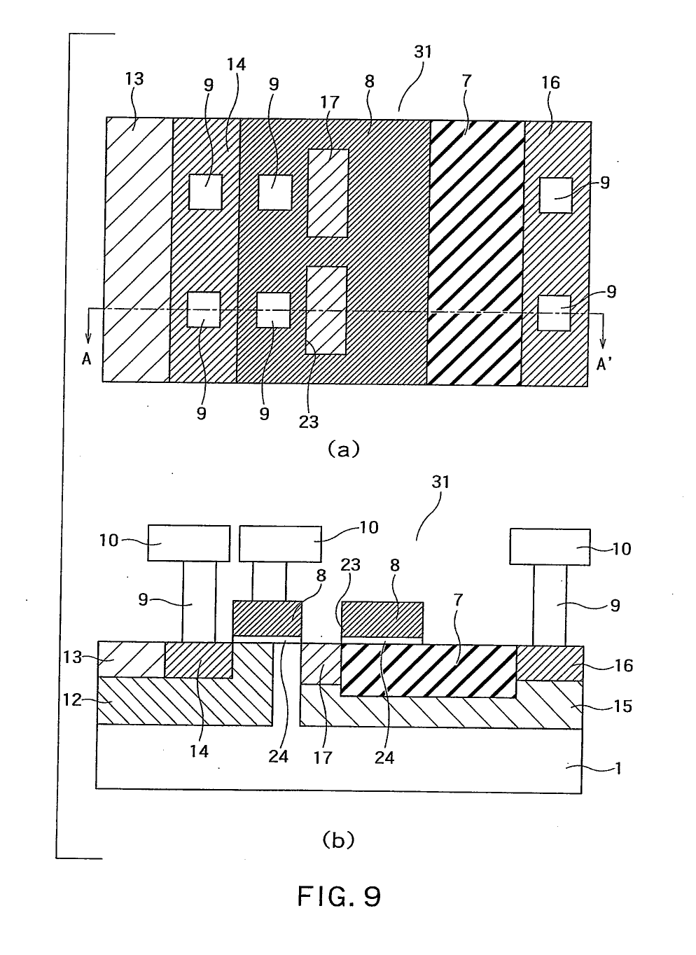

Similarly to the first embodiment, the LDMOS 31 of the second embodiment can be applied to the P-type channel semiconductor device. FIG. 9 (a) is a plan view of a P-type channel LDMOS 31 according to a first modification of the second embodiment, and FIG. 9 (b) is a sectional view of the P-type channel LDMOS 31. Because the first modification of the second embodiment is similar to the first modification of the first embodiment, the description will not be repeated. For the sake of easy understanding, the interconnection layer 10 is not illustrated in FIG. 9 (a).

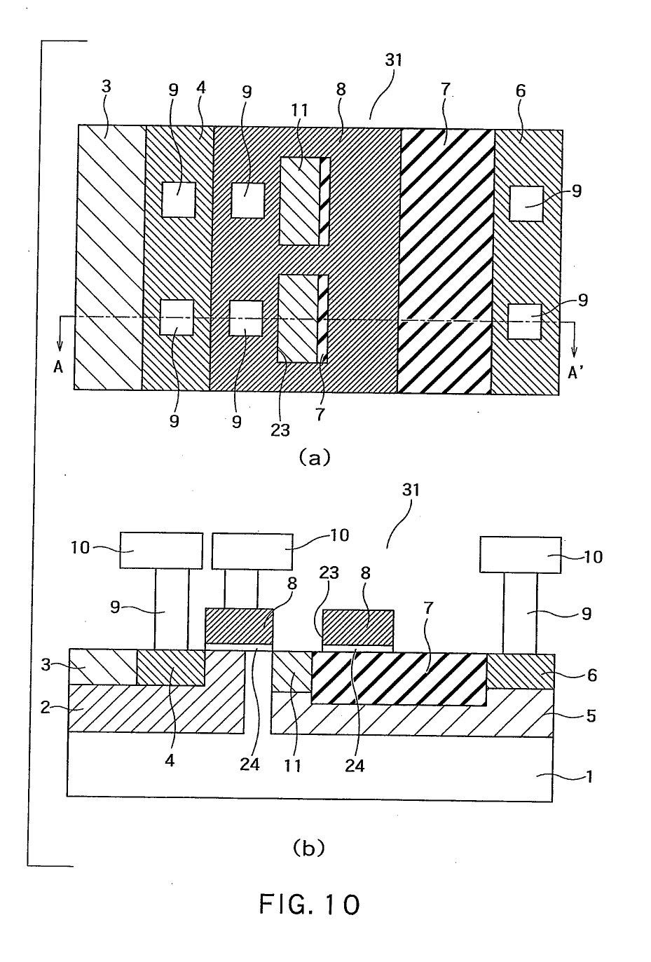

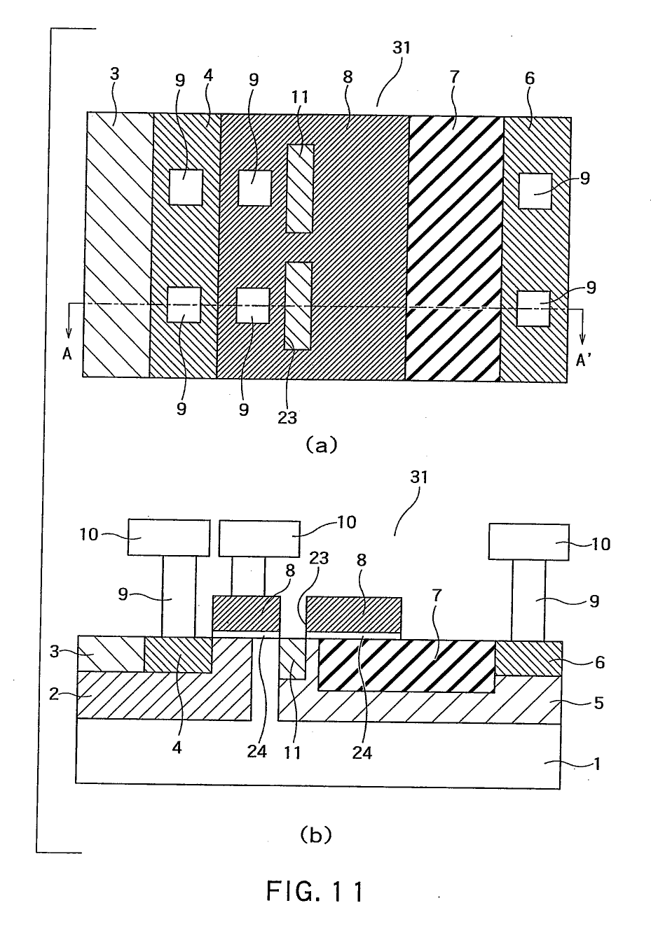

In the second embodiment, similarly to the second and third modifications of the first embodiment, the side surface on the drain side of the opening 23 can be located on the source side from the source side edge of the field oxide film 7, and the side surface on the drain side of the opening 23 can be located on the drain side from the source side edge of the field oxide film 7. FIGS. 10 and 11 illustrate second and third modifications of the second embodiment.

According to the second embodiment, the gate electrode 8 and the gate insulator 24 are used as the mask instead of the patterning performed with the resist mask in the LDMOS producing process of the related art, and the N-type drift region 11 is accurately formed at the desired position, so that the variation of the distance between the source region 4 and the drift region 11 can be reduced. Therefore, the variations of the drain-to-source Breakdown Voltage and the on-resistance, which are the main characteristics of the LDMOS 31, can be reduced. According to the second embodiment, the increases of the production time and the production cost can be avoided with the gate electrode 8 and the gate insulator 24 as the mask.

### Third Embodiment

In the first and second embodiments, the opening 23 is formed in the gate electrode 8 on the N-type drift region 11, namely, the gate electrode 8 and the gate insulator 24 on the P-type body region 2 are not completely separated from the gate electrode 8 and the gate insulator 24 on the field oxide film 7. On the other hand, in a third embodiment of the invention, the gate electrode 8 (first gate electrode) and the gate insulator 24 (first gate insulator) on the P-type body region 2 are completely separated from the gate electrode 8 (second gate electrode) and the gate insulator 24 (second gate insulator) on the field oxide film 7 while the N-type drift region 11 is sandwiched therebetween. In the third embodiment, the separated gate electrodes 8 may have the same potential by connecting the separated gate electrodes 8 with the interconnection layer 10. Alternatively, the separated gate electrodes 8 may be connected by another interconnection layer except the interconnection layer 10. In the structure of the third embodiment, the N-type drift region 11 through which the carrier passes is formed wider than that of the first and second embodiments, so that the on-resistance can further be reduced.

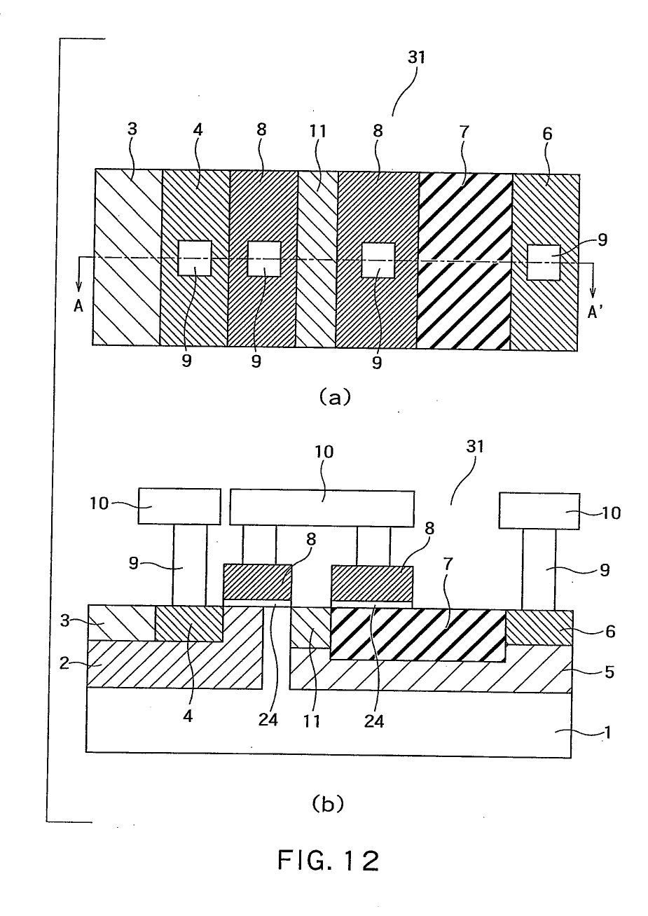

The semiconductor device 31 of the third embodiment will be described with reference to FIG. 12. Although the N-type channel LDMOS is described by way of example in the third embodiment, the invention can be applied to other kinds of semiconductor devices.

FIG. 12 (a) is a plan view of the LDMOS (semiconductor device) 31 of the third embodiment, and FIG. 12 (b) is a sectional view of the LDMOS 31. FIG. 12 (b) is the sectional view taken on a line A-A′ of FIG. 12 (a). The N-type channel LDMOS 31 of the third embodiment differs from that of the first embodiment in the shapes of the gate electrode 8 and the gate insulator 24 and the shape of the N-type drift region 11. Accordingly, different points will be described below.

As illustrated in FIG. 12 (a), the gate electrode covers the surface of the semiconductor substrate 1 from the drain side edge portion of the P-type body region 2 to the source side edge portion of the field oxide film 7, and the gate electrode 8 is divided into a first gate electrode 8 on the source side and a second gate electrode 8 on a second drain side while the surface of the N-type drift region 11 is sandwiched therebetween. In other words, the gate electrode 8 is divided into the first gate electrode 8 and the second gate electrode 8, and the N-type drift region 11 is formed in the semiconductor substrate 1 between the first gate electrode 8 and the second gate electrode 8. For example, a distance between the first gate electrode 8 and the second gate electrode 8 is 0.2 μm. There is no particular limitation to the distance. For example, 0.18 μm by 0.18 μm electrode regions 9 are disposed on the N-type source region 4, the gate electrode 8, and the N-type drain region 6. In FIG. 12 (a), the electrode region 9 on the N-type source region 4, the electrode region 9 on the gate electrode 8, and the electrode region 9 on the N-type drain region 6 are disposed in line. However, the invention is not limited to the disposition of FIG. 12 (a). It is only necessary to dispose the electrode region 9 of the N-type source region 4 on the N-type source region 4, it is only necessary to dispose the electrode region 9 of the gate electrode 8 on the gate electrode 8, and it is only necessary to dispose the electrode region 9 of the N-type drain region 6 on the N-type drain region 6. For the sake of easy understanding, the interconnection layer 10 is not illustrated in FIG. 12 (a).

Then, as illustrated in FIG. 12(b), the N-type drift region 11 is formed between the P-type body region 2 and the field oxide film 7 in the upper portion of the N-type drift region 5 so as to be separated from the P-type body region 2 and so as to be in contact with the side surface on the source side of the field oxide film 7. The gate electrode 8 is formed on the surface of the semiconductor substrate 1, the gate electrode 8 is divided into the first gate electrode film 8 on the source side and the second gate electrode 8 on the second drain side while the surface of the N-type drift region 11 is sandwiched between the first gate electrode film 8 and the second gate electrode 8, the first gate electrode film 8 covers the P-type body region 2 from the drain side edge portion of the P-type body region 2 to the source side edge portion of the field oxide film 7 via the gate insulator 24 (first gate insulator), the second gate electrode film 8 covers the field oxide film 7 via the insulator 24 (second gate insulator).The electrode regions 9 are formed on the gate electrode 8, the N-type source region 4, and the N-type drain region 6, and the interconnection layers 10 are formed on the electrode regions 9, respectively. The first gate electrode 8 and the second gate electrode 8 are electrically connected by the interconnection layer 10. In FIG. 10 (b), the separated gate electrodes 8 are connected by the interconnection layer 10. Alternatively, the separated gate electrodes 8 may be connected by another interconnection layer except the interconnection layer 10.

Because a method of producing the N-type channel LDMOS 31 of the third embodiment is similar to that of the first embodiment, the description will not be repeated.

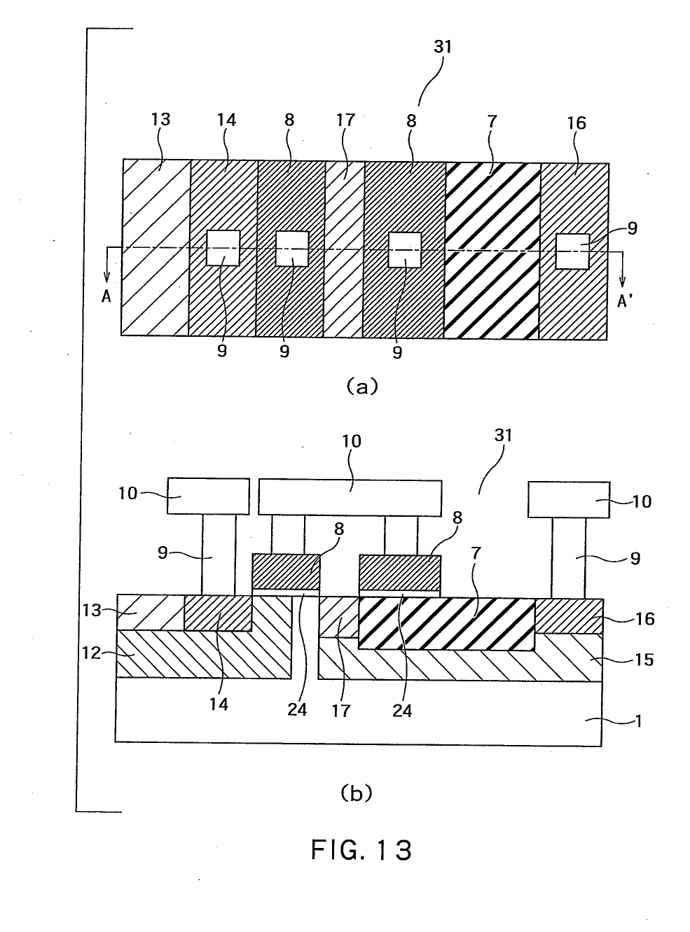

Similarly to the first embodiment, the LDMOS 31 of the third embodiment can be applied to the P-type channel semiconductor device. FIG. 13 (a) is a plan view of a P-type channel LDMOS 31 according to a first modification of the second embodiment, and FIG. 13 (b) is a sectional view of the P-type channel LDMOS 31. Because the first modification of the second embodiment is similar to the first modification of the first embodiment, the description will not be repeated.

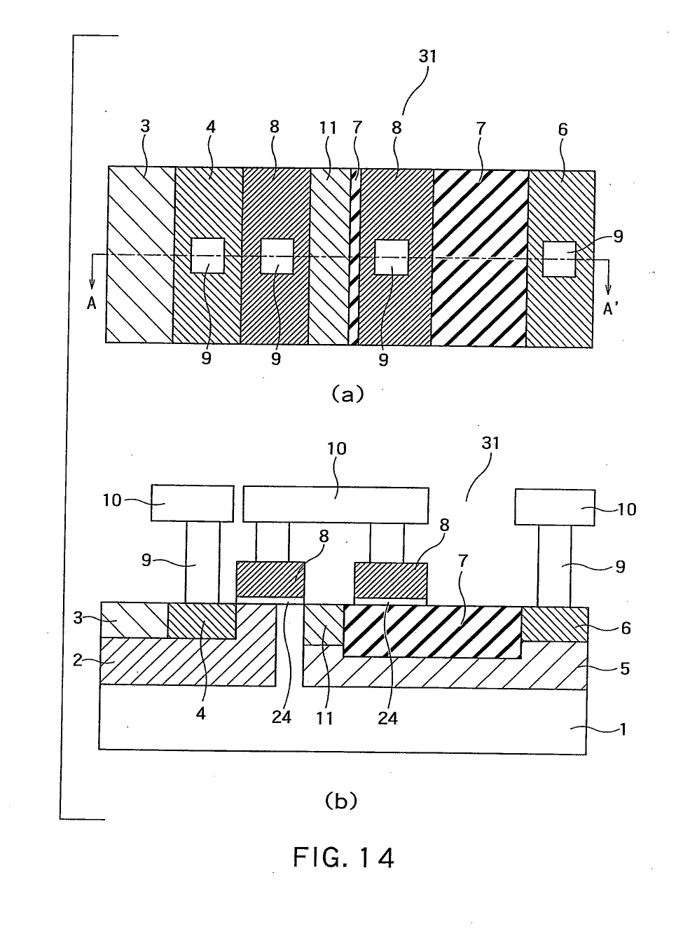

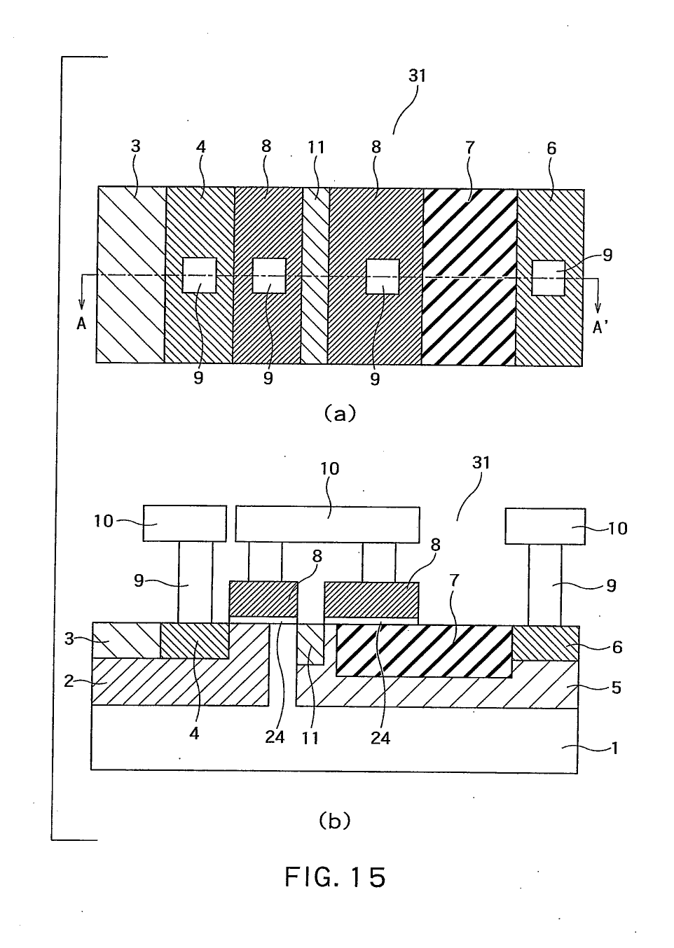

In the third embodiment, as illustrated in FIGS. 13 (a) and 13 (b), the second gate electrode 8, with which the field oxide film 7 is covered via the gate insulator 24 (second gate insulator), is positioned such that the side surface on the source side of the second gate electrode 8 is aligned with the source side edge of the field oxide film 7. Alternatively, similarly to the second and third modifications of the first embodiment, the side surface on the source side of the second gate electrode 8 can be located on the source side from the source side edge of the field oxide film 7, or the side surface on the source side of the second gate electrode 8 can be located on the drain side from the source side edge of the field oxide film 7. FIGS. 14 and 15 illustrate second and third modifications of the third embodiment.

According to the third embodiment, the gate electrode 8 and the gate insulator 24 are used as the mask instead of the patterning performed with the resist mask in the LDMOS producing process of the related art, and the N-type drift region 11 is accurately formed at the desired position, so that the variation of the distance between the N-type source region 4 and the N-type drift region 11 can be reduced. Therefore, the variations of the drain-to-source Breakdown Voltage and the on-resistance, which are the main characteristics of the LDMOS 31, can be reduced. The on-resistance can further be reduced because of the wide N-type drift region 11. According to the third embodiment, the increases of the production time and the production cost can be avoided with the gate electrode 8 and the gate insulator 24 as the mask.

In the first to third embodiments, it is not always necessary that the silicon substrate be used as the semiconductor substrate 1. Alternatively, other substrates made of germanium, silicon germanium, silicon carbide, and gallium nitride may be used as the semiconductor substrate 1.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and the equivalents are intended to cover such forms or modifications as would fall within the scope and spirit of the inventions.

1. A semiconductor device comprising:
a substrate;
a second conductive type source region formed in part of the substrate;
a second conductive type drain region formed in part of the substrate so as to be separated from the second conductive type source region;
a first conductive type channel region formed in the substrate between the second conductive type source region and the second conductive type drain region while being adjacent to the second conductive type source region;
a second conductive type drift region formed between the first conductive type channel region and the second conductive type drain region while being adjacent to the second conductive type drain region;
an insulator film buried on a surface of the second conductive type drift region while separated from the first conductive type channel region; and
a gate electrode including an opening between the first conductive type channel region and the insulator film, and covering a surface of the substrate from the first conductive type channel region to part of the insulator film via a gate insulator,
wherein the second conductive type drift region comprises a second portion of the second conductive type drift region formed in the substrate below the opening, and a first portion of the second conductive type drift region, the first portion being a portion other than the second portion in the second conductive type drift region.

2. The semiconductor device according to claim 1, wherein an impurity concentration of the second portion of the second conductive type drift region is higher than an impurity concentration of the first portion and lower than an impurity concentration of the second conductive type drain region.

3. The semiconductor device according to claim 1, wherein a side surface on the second conductive type drain region side of the opening is located on the second conductive type drain region side compared with a position of a side edge of the second conductive type source region of the insulator film.

4. The semiconductor device according to claim 1, wherein the side surface on the second conductive type drain region side of the opening is located on the second conductive type source region side compared with the position of the side edge of the second conductive type source region of the insulator film.

5. The semiconductor device according to claim 1, wherein the side surface on the second conductive type drain region side of the opening is located at a position identical to the position of the side edge of the second conductive type source region of the insulator film.

6. The semiconductor device according to claim 1, wherein a depth of the second portion in the second conductive type drift region is shallower than that of the first portion.

7. The semiconductor device according to claim 1, wherein the gate electrode includes the plurality of openings, and the plurality of second portions of the second conductive type drift region is formed in the substrate below the plurality of openings.

8. The semiconductor device according to claim 7, wherein impurity concentrations of the plurality of second portions in the second conductive type drift region are higher than the impurity concentration of the first portion and lower than the impurity concentration of the second conductive type drain region.

9. The semiconductor device according to claim 7, wherein a side surface on the second conductive type drain region side of each of the openings is located on the second conductive type drain region side compared with the position of the side edge of the second conductive type source region of the insulator film.

10. The semiconductor device according to claim 7, wherein the side surface on the second conductive type drain region side of each of the openings is located on the second conductive type source region side compared with the position of the side edge of the second conductive type source region of the insulator film.

11. The semiconductor device according to claim 7, wherein the side surface on the second conductive type drain region side of each of the openings is located at the position identical to the position of the side edge of the second conductive type source region of the insulator film.

12. A semiconductor device comprising:
a substrate;
a second conductive type source region formed in part of the substrate;
a second conductive type drain region formed in part of the substrate so as to be separated from the second conductive type source region;
a first conductive type channel region formed in the substrate between the second conductive type source region and the second conductive type drain region while being adjacent to the second conductive type source region;
a second conductive type drift region formed between the first conductive type channel region and the second conductive type drain region while being adjacent to the second conductive type drain region;
an insulator film buried on a surface of the second conductive type drift region while separated from the first conductive type channel region;
a first gate electrode covering the first conductive type channel region via a first gate insulator; and
a second gate electrode covering the insulator film via a second gate insulator,
wherein the second conductive type drift region comprises a second portion of the second conductive type drift region formed in the substrate between the first gate insulator and the second gate insulator and a first portion of the second conductive type drift region, the first portion being a portion other than the second portion in the second conductive type drift region.

13. The semiconductor device according to claim 12, wherein an impurity concentration of the second portion of the second conductive type drift region is higher than an impurity concentration of the first portion and lower than an impurity concentration of the second conductive type drain region.

14. The semiconductor device according to claim 12, wherein the first gate electrode and the second gate electrode are electrically connected by an interconnection layer.

15. The semiconductor device according to claim 12, wherein side surfaces on a second conductive type source region side of the second gate electrode and the second gate insulator are located on the second conductive type drain region side compared with a position of a side edge of the second conductive type source region of the insulator film.

16. The semiconductor device according to claim 12, wherein the side surfaces on the second conductive type source region side of the second gate electrode and the second gate insulator are located on the second conductive type source region side compared with the position of the side edge of the second conductive type source region of the insulator film.

17. The semiconductor device according to claim 12, wherein the side surfaces on the second conductive type source region side of the second gate electrode and the second gate insulator are located at a position identical to the position of the side edge of the second conductive type source region of the insulator film.

18. A semiconductor device producing method comprising:
forming a first second-conductive-type drift region in part of a substrate, the first second-conductive-type drift region including an insulator film on a surface thereof;
forming a first conductive type channel region in part of the substrate;
forming a gate electrode so as to cover the surface of the substrate from the first conductive type channel region to part of the insulator film via a gate insulator;
forming an opening between the first conductive type channel region and the insulator film in the gate electrode and the gate insulator; and
adding an impurity through the opening with the gate electrode and the gate insulator as a mask to form a second second-conductive-type drift region connected to the first second-conductive-type drift region.

19. The semiconductor device producing method according to claim 18, wherein the opening is formed such that a side surface on the second conductive type drain region side of the opening is located on the second conductive type drain region side compared with a position of a side edge of the second conductive type source region of the insulator film.

20. The semiconductor device producing method according to claim 18, wherein the opening is formed such that a side surface on the second conductive type drain region side of the opening is located on the second conductive type source region side compared with the position of the side edge of the second conductive type source region of the insulator film.
